(19) United States
(12) Patent Application Publication
(10) Pub. No.: US 2005/0104113 A1
(43) Pub. Date: May 19, 2005

(54) Electrode forming method, capacitor element and fabricating method therefor

(75) Inventors: Takumi Mikawa, Shiga (JP); Hiroshige Hirano, Nara (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/986,316

(22) Filed: Nov. 12, 2004

(30) Foreign Application Priority Data
Nov. 14, 2003 (JP) 2003-384788

(51) Int. Cl. H01L 21/00; H01L 21/8242; H01L 27/108; H01L 29/76

(52) U.S. Cl. 257/310; 438/3; 438/717

(57) ABSTRACT

An electrode forming method includes the steps of: forming a conductive film on a substrate; forming, on the conductive film, a first mask pattern extending in a first direction; forming a conductive film pattern by etching the conductive film using the first mask pattern; removing the first mask pattern existing on the conductive film pattern; forming, on the substrate and on the conductive film pattern, a second mask pattern extending in a second direction different from the first direction; and forming an electrode by etching the conductive film pattern using the second mask pattern.

### CROSS-REFERENCE TO RELATED APPLICATION

The entire disclosure of Japanese Patent Application No. 2003-384788 filed on Nov. 14, 2003 including specification, drawings and claims are incorporated herein by reference.

### BACKGROUND OF THE INVENTION

The present invention relates to a capacitor element including a capacitor insulating film consisting of a ferroelectric film or a high dielectric film made of a dielectric material, and a method for fabricating the capacitor element, and in particular, to a method for forming an electrode.

In the development of ferroelectric capacitor element including a capacitor insulating film consisting of a ferroelectric film, small-capacity ferroelectric capacitor elements of 1 to 64 Kbits adopting a planar structure are beginning to be in mass production. Recently, in order to reduce the cell size, large-capacity ferroelectric capacitor elements of 256 Kbits to 4 Mbits adopting a stack structure, in which contact plugs electrically connecting with semiconductor substrates are disposed right under capacitor lower electrodes, are in the core of the development.

In general, miniaturization of ferroelectric capacitor elements is behind that of basic CMOSs. One reason of this is a difficulty in microprocessing performed to electrodes and dielectric films made of a noble metal material such as platinum or iridium. Conventionally, a capacitor upper electrode, a capacitor insulating film and a capacitor lower electrode have been collectively etched using one mask so as to realize miniaturization of a cell by eliminating a need to estimate a mask alignment margin which is required for etching performed by using separate masks. In this way, a ferroelectric capacitor element of a stack structure has been formed (for example, see Japanese Patent Application Laid-open No. 9-162311 (Page 5, FIG. 1)).

The structure of a conventional ferroelectric memory including a capacitor element will be described below with reference to FIG. 18.

As shown in FIG. 18, an element separation insulating film 101 for defining an element forming region is formed on a semiconductor substrate 100. On the surface of the element separation forming region, n-type impurity diffusion layers (phosphorus) 102 and 103 are formed. Further, a transistor for switch, consisting of a gate insulating film 104 and a gate electrode 105, is formed on the semiconductor substrate 100. Note that the gate electrode 105 forms a word line. Further, a first interlayer insulating film 106 is formed on the semiconductor substrate 100 so as to cover the transistor for switch.

In the first interlayer insulating film 106, a bit line 107 connecting with the n-type impurity diffusion layer 102 is formed. The material of the bit line 107 is a laminated film formed of metallic suicide and polycrystal silicon. On the first interlayer insulating film 106 and the bit line 107, a second interlayer insulating film 108 is formed. In the second interlayer insulating film 108 and the first interlayer insulating film 106, there is formed a memory contact 109 made of polycrystal silicon, the lower end of which connects with the n-type impurity diffusion layer 103.

On the second interlayer insulating film 108 and the memory contact 109, a diffusion preventive layer 110 made of titanium nitride with a thickness of 50 nm and a capacitor lower electrode 111 consisting of a platinum film with a thickness of 200 nm are formed by sputtering in sequence from the bottom. Note that the diffusion preventive layer 110 serves to prevent the diffusion of oxygen constituting the lower electrode 111 and the memory contact 109 to the polycrystal silicon. On the capacitor lower electrode 111, a capacitor insulating film 112 consisting of a ferroelectric film is formed. The capacitor insulating film 112 is so formed that a thin film made of lead zirconate titanate (Pb(Zr_{0.5}Ti_{0.5})O₃) with a thickness of about 150 nm is formed by the reactive deposition, and then the film is crystallized by a heat treatment in oxygen atmosphere at 650° C. for 30 seconds. On the capacitor insulating film 112, a capacitor upper electrode 113 consisting of a platinum film with a thickness of 50 nm is formed by sputtering.

A capacitor element composed of the capacitor lower electrode 111, the capacitor insulating film 112 and the capacitor upper electrode 113 is formed in such a manner that the capacitor upper electrode 113 is first patterned by sputter etching using a hard mask with a film thickness of 350 nm to which a photoresist pattern is transferred, and then the capacitor insulating film 112 is processed by using a mixed gas of CF₄ and Aᵣ, and then the capacitor lower electrode 111 is processed by sputter etching. Further, when forming the capacitor element, the conditions of dry etching are adjusted so as to proceed the etching in equal directions and the sectional processing shape is designed to be a trapezoid in which an angle of the hypotenuse to the substrate is 75° or less, in order to prevent a platinum protruded deposit from remaining on the side walls of the capacitor lower electrode 110 and to prevent a deposit consisting of the constitutive element of the ferroelectric film from remaining on its outer periphery.

### SUMMARY OF THE INVENTION

In a conventional method for fabricating a capacitor element, a capacitor element is processed by using a dot pattern of so-called remained mark, whereby there is a limitation that an area required for the adhesion of the photoresist must be secured. That is, since the resist is isolated in the dot pattern, the adhesive area of the resist and the base film is reduced when miniaturizing the electrode size, whereby the resist may be peeled when etching, resulting in a defective pattern. Further, the resist may be peeled or destructed in the lithography stage, depending on the compatibility between the resist and the base film or on the area of an electrode to be formed.

Further, when comparing a dot pattern with a line pattern, an influence of two-dimensional light must be considered for a dot pattern generally, although only an influence of one-dimensional light should be considered for a line pattern. Therefore, in the case of using a dot pattern, the resolution is lower, and further the focus depth is smaller, compared with the case of using a line pattern. That is, a dot pattern is less advantageous than a line pattern in microprocessing a capacitor element.

Considering the above problems, it is an object of the present invention to promote miniaturization of a dielectric capacitor having a stack structure without depending on materials used for an electrode and on the electrode area.

In order to solve the aforementioned problems, an electrode forming method according to the present invention comprises the steps of: forming a conductive film on a substrate; forming, on the conductive film, a first mask pattern extending in a first direction; forming a conductive film pattern by etching the conductive film using the first mask pattern; removing the first mask pattern; forming, on the substrate and on the conductive film pattern, a second mask pattern extending in a second direction different from the first direction; and forming electrodes by etching the conductive film pattern using the second mask pattern.

According to the electrode forming method of the present invention, the conductive film pattern is formed by using the first mask pattern extending in the first direction, and then the electrodes are formed at positions where the first direction crosses the second direction, by using the second mask pattern extending in the second direction. This enables to secure the adhesive area of the resist and the base film sufficiently. Thus, it is possible to prevent the resist from being peeled or destructed at the time of lithography and etching when forming the miniaturized electrodes. Thereby, a defective pattern is not caused, so that fine capacitor elements can be formed. Further, the mask patterns extending in the first and second directions are excellent in the resolution and the focus depth compared with the case of using a dot pattern, enabling to promote microprocessing of the electrodes.

In the electrode forming method according to the present invention, the conductive film may include a metallic material. This is because that the electrode forming method of the present invention prevents the resist from being peeled or destructed at the time of lithography or etching so as not to cause a defective pattern, whereby even a metal film which easily causes a defective pattern due to halation or the like can be used positively as an electrode.

In the electrode forming method of the present invention, the aspect ratio of the electrode may be 1 or more. This is because that the electrode forming method of the present invention prevents the resist from being peeled or destructed at the time of lithography or etching so as not to cause a defective pattern, whereby miniaturization of the electrodes with high aspect ratio can be realized easily.

A capacitor element fabricating method according to the present invention comprises the steps of: forming a first conductive film on a substrate; forming, on the first conductive film, a first mask pattern extending in a first direction; forming a conductive film pattern by etching the first conductive film using the first mask pattern; removing the first mask pattern; forming, on the substrate, a dielectric film and a second conductive film in sequence from the bottom so as to cover the conductive film pattern; forming, on the second conductive film, a second mask pattern extending in a second direction different from the first direction; and by etching the second conductive film, the dielectric film and the conductive film pattern by using the second mask pattern, forming a capacitor element composed of capacitor lower electrodes consisting of the conductive film pattern, a capacitor insulating film consisting of the dielectric film, and a capacitor upper electrode consisting of the second conductive film.

According to the capacitor element fabricating method of the present invention, the conductive film pattern is first formed by using the first mask pattern extending in the first direction, and then the capacitor element with the capacitor lower electrodes at positions where the first direction crosses the second direction are formed by using the second mask pattern extending in the second direction. This enables to secure the adhesive area of the resist and the base film sufficiently. Thus, it is possible to prevent the resist from being peeled or destructed at the time of lithography and etching when forming the miniaturized capacitor element. Thereby, a defective pattern is not caused, so that a fine capacitor element can be formed. Further, since the second conductive film, the dielectric film and the conductive film pattern are etched by using the second mask pattern, the capacitor element can be formed in a self-aligned manner. Moreover, the mask patterns extending in the first and second directions are excellent in the resolution and the focus depth compared with the case of using a dot pattern, enabling to promote microprocessing of the capacitor element.

In the capacitor element fabricating method according to the present invention, at least one of the first conductive film and the second conductive film may include a metallic material. This is because that the capacitor element fabricating method of the present invention prevents the resist from being peeled or destructed at the time of lithography or etching so as not to cause a defective pattern, whereby even a metal film which easily causes a defective pattern due to halation or the like can be used positively as a capacitor upper electrode or a capacitor lower electrode. For example, a metal film which is advantageous in the crystal orientation of the dielectric film, such as a platinum film, can be used.

A capacitor element according to the present invention comprises: a plurality of capacitor lower electrodes aligned in a prescribed direction and side faces of which are positioned on a face extending in the prescribed direction; a capacitor insulating film formed on the plurality of capacitor lower electrodes so as to extend in the prescribed direction; and a capacitor upper electrode formed on the capacitor insulating film so as to extend in the prescribed direction, wherein the side faces of the plurality of capacitor lower electrodes positioned on the face, side faces of the capacitor insulating film extending in the prescribed direction, and side faces of the capacitor upper electrode extending in the prescribed direction are flush with one another.

According to the capacitor element of the present invention, the configuration of the side faces of the capacitor element can be formed in a self-aligned manner, enabling to miniaturize the capacitor element and also to promote miniaturization of the cell in the capacitor element of a type in which the capacity of the capacitor lower element is defined.

In the capacitor element of the present invention, at least one of the capacitor lower electrode and the capacitor upper electrode may include platinum or iridium. This is because that in fabricating the capacitor element of the present invention, the resist is prevented from being peeled or destructed at the time of lithography or etching so as not to cause a defective pattern, whereby even a metal film which easily causes a defective pattern due to halation or the like can be used positively as a capacitor upper electrode or a capacitor lower electrode. For example, a metal film which is advantageous in the crystal orientation of the dielectric film, such as a platinum film, can be used.

In the capacitor element of the present invention, the capacitor insulating film may be made of a ferroelectric material having a bismuth layered perovskite structure, lead zirconate titanate, barium strontium titanate, or tantalum pentoxide. This is because that in fabricating the capacitor element of the present invention, the resist is prevented from being peeled or destructed at the time of lithography or etching so as not to cause a defective pattern, whereby a material with a difficulty in processing can be used for the capacitor insulating film.

As described above, according to the capacitor element and its fabricating method of the present invention, the conductive film pattern is first formed by using the first mask pattern extending in the first direction, and then the capacitor insulating film and the capacitor upper electrode are formed at positions where the first direction crosses the second direction, by using the second mask pattern extending in the second direction. This enables to secure the adhesive area of the resist and the base film sufficiently. Thus, it is possible to prevent the resist from being peeled or destructed at the time of lithography and etching when forming the miniaturized capacitor element. Thereby, a defective pattern is not caused, so that a fine capacitor element can be formed. Further, since the second conductive film, the dielectric film and the conductive film pattern are etched by using the second mask pattern, the capacitor element can be formed in a self-aligned manner. Moreover, the mask patterns extending in the first and second directions are excellent in the resolution and the focus depth compared with the case of using a dot pattern, enabling to promote microprocessing of the capacitor element.

### BRIEF DESCRIPTION OF THE DRAWINGS

FIG. 1A is a process sectional view showing an electrode forming method according to a first embodiment of the present invention, and FIG. 1B is a process plan view showing the electrode forming method according to the first embodiment of the present invention.

FIG. 2A is a process sectional view showing the electrode forming method according to the first embodiment of the present invention, and FIG. 2B is a process plan view showing the electrode forming method according to the first embodiment of the present invention.

FIG. 3A is a process sectional view showing the electrode forming method according to the first embodiment of the present invention, and FIG. 3B is a process plan view showing the electrode forming method according to the first embodiment of the present invention.

FIG. 4A is a process sectional view showing the electrode forming method according to the first embodiment of the present invention, and FIG. 4B is a process plan view showing the electrode forming method according to the first embodiment of the present invention.

FIG. 5A is a process sectional view showing the electrode forming method according to the first embodiment of the present invention, and FIG. 5B is a process plan view showing the electrode forming method according to the first embodiment of the present invention.

FIG. 6A is a process sectional view showing an electrode forming method according to a second embodiment of the present invention, and FIG. 6B is a process plan view showing the electrode forming method according to the second embodiment of the present invention.

FIG. 7A is a process sectional view showing the electrode forming method according to the second embodiment of the present invention, and FIG. 7B is a process plan view showing the electrode forming method according to the second embodiment of the present invention.

FIG. 8A is a process sectional view showing the electrode forming method according to the second embodiment of the present invention, and FIG. 8B is a process plan view showing the electrode forming method according to the second embodiment of the present invention.

FIG. 9A is a process sectional view showing the electrode forming method according to the second embodiment of the present invention, and FIG. 9B is a process plan view showing the electrode forming method according to the second embodiment of the present invention.

FIG. 10A is a process sectional view showing the electrode forming method according to the second embodiment of the present invention, and FIG. 10B is a process plan view showing the electrode forming method according to the second embodiment of the present invention.

FIG. 11A is a process sectional view showing a capacitor element fabricating method according to a third embodiment of the present invention, and FIG. 11B is a process plan view showing the capacitor element fabricating method according to the third embodiment of the present invention.

FIG. 12A is a process sectional view showing the capacitor element fabricating method according to the third embodiment of the present invention, and FIG. 12B is a process plan view showing the capacitor element fabricating method according to the third embodiment of the present invention.

FIG. 13A is a process sectional view showing the capacitor element fabricating method according to the third embodiment of the present invention, and FIG. 13B is a process plan view showing the capacitor element fabricating method according to the third embodiment of the present invention.

FIG. 14A is a process sectional view showing the capacitor element fabricating method according to the third embodiment of the present invention, and FIG. 14B is a process plan view showing the capacitor element fabricating method according to the third embodiment of the present invention.

FIG. 15A is a process sectional view showing the capacitor element fabricating method according to the third embodiment of the present invention, and FIG. 15B is a process plan view showing the capacitor element fabricating method according to the third embodiment of the present invention.

FIG. 16A is a process sectional view showing the capacitor element fabricating method according to the third embodiment of the present invention, and FIG. 16B is a process plan view showing the capacitor element fabricating method according to the third embodiment of the present invention.

FIGS. 17A and 17B are sectional views showing a structure of a capacitor element according to a fourth embodiment of the present invention, and FIG. 17C is a plan view showing the structure of the capacitor element according to the fourth embodiment of the present invention.

FIG. 18 is a sectional view showing a structure of a conventional capacitor element.

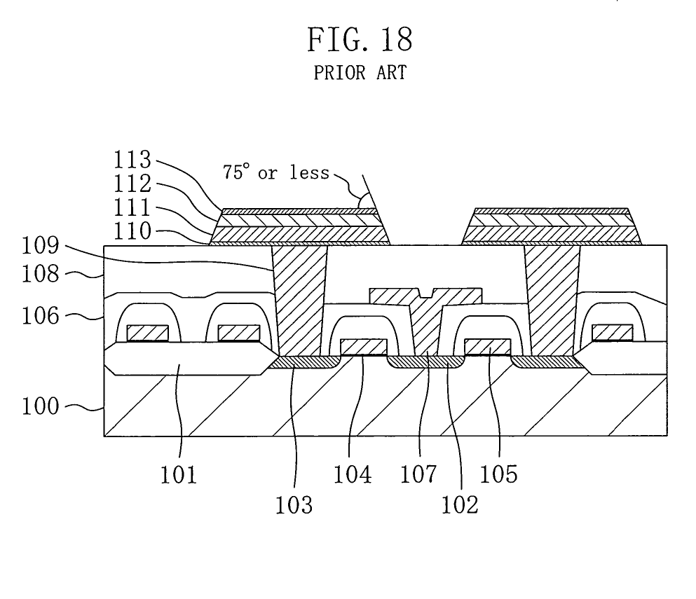

### PREFERRED EMBODIMENTS OF THE INVENTION

Hereinafter, each embodiment of the present invention will be described with reference to the drawings.

### First Embodiment

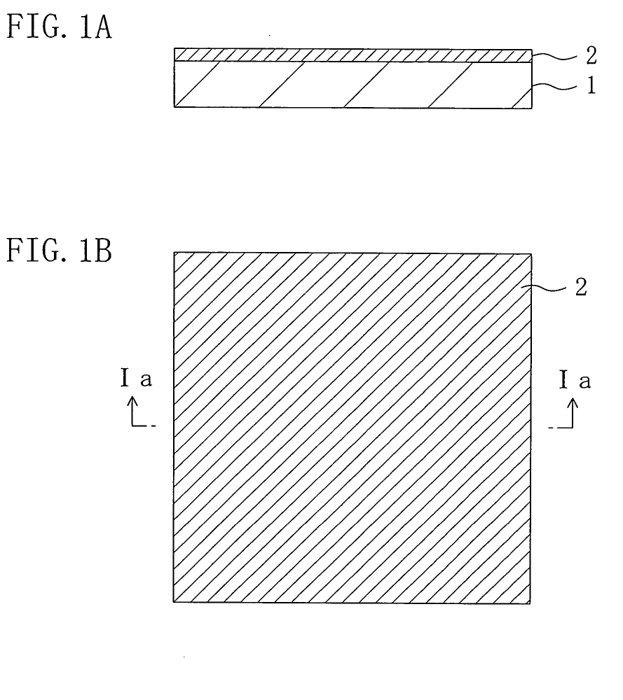

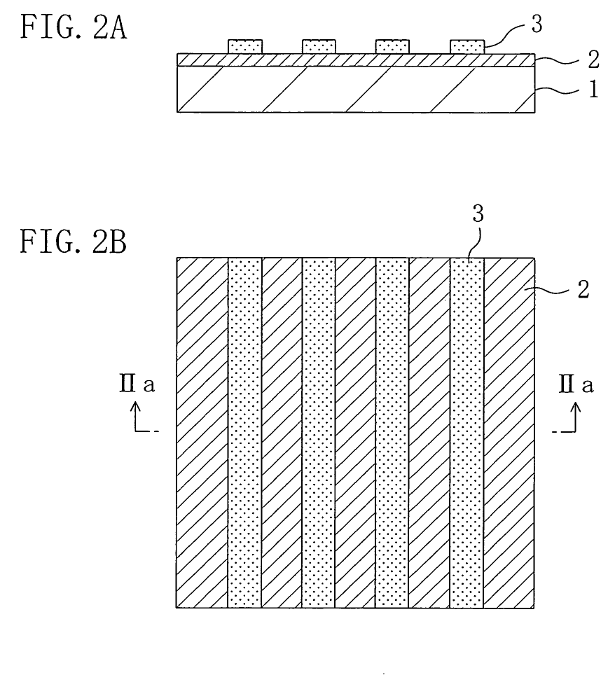

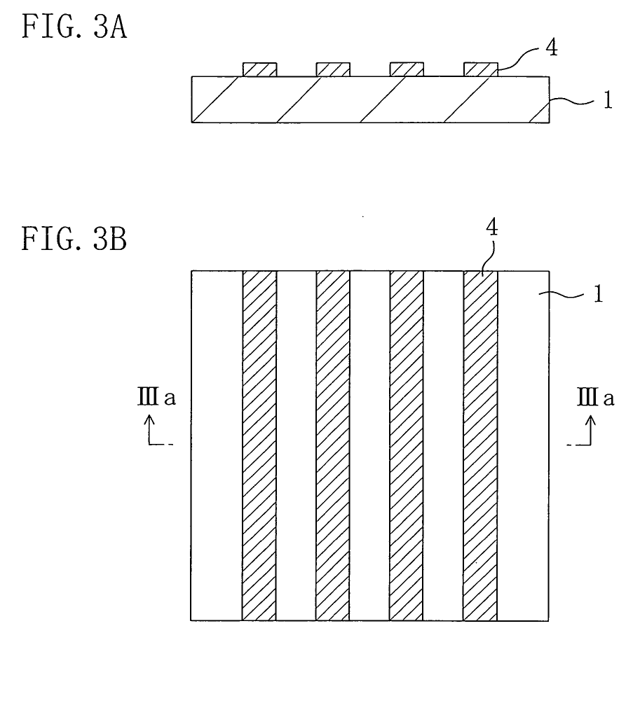

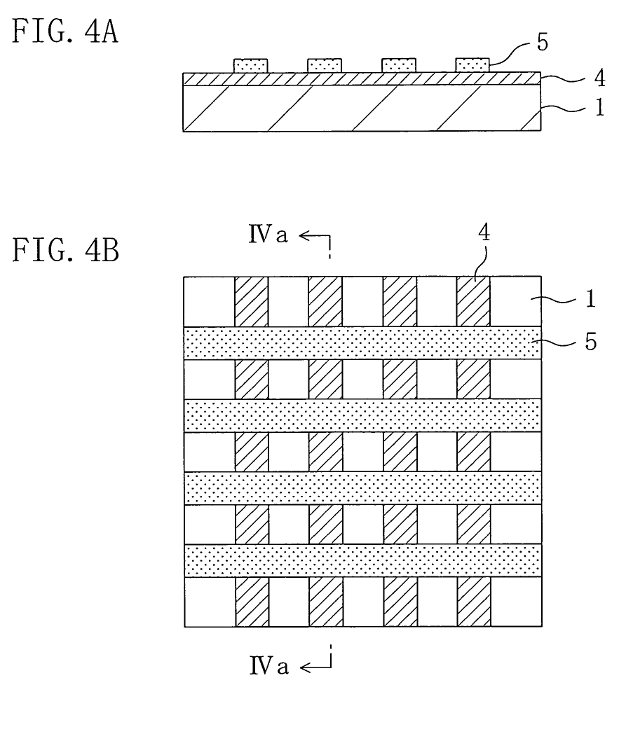

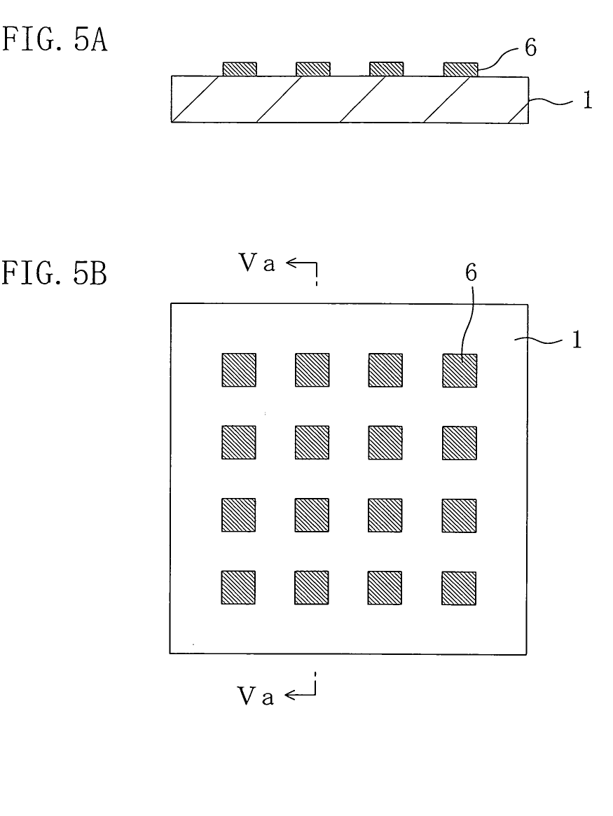

An electrode forming method according to a first embodiment of the present invention will be described below with reference to FIGS. 1A, 1B, 2A, 2B, 3A, 3B, 4A, 4B, 5A and 5B. FIGS. 1A, 2A, 3A, 4A and 5A are sequential process sectional views showing an electrode forming method, and FIGS. 1B, 2B, 3B, 4B and 5B are sequential process plan views showing the electrode forming method. Further, FIGS. 1A, 2A, 3A, 4A and 5A are sectional views taken along the line Ia-Ia of FIG. 1B, the line Ia-Ia of FIG. 2B, the line IIIa-IIIa of FIG. 3B, the line IVa-IVa of FIG. 4B, and the line Va-Va of FIG. 5B, respectively.

First, as shown in FIGS. 1A and 1B, a conductive film 2 consisting of a platinum film with a thickness of 50 to 200 nm is deposited on a semiconductor substrate 1.

Next, as shown in FIGS. 2A and 2B, a linear first mask pattern 3, consisting of photoresist and extending in a first direction, is formed on the conductive film 2 by using a desired mask. Herein, the linear mask pattern is cut out into, for example, a rectangular shape (the same is applied in the following embodiments.).

In this way, by using a linear mask pattern as the first mask pattern 3, a narrower pattern can be resolved and a better focus depth can be achieved compared with a case of using a dotted mask pattern of the conventional example, with the same lithography technique. Further, by using the linear mask pattern, the adhesive area of the first mask pattern 3 to the conductive film 2 can be secured sufficiently, compared with the case of using the dotted mask pattern of the conventional example. Thus, it is advantageous to use a linear mask pattern for realizing miniaturization of electrodes.

Next, as shown in FIGS. 3A and 3B, by etching the conductive film 2 using the first mask pattern 3, a conductive film pattern 4 extending in the first direction is formed. Then, the first mask pattern 3 existing on the conductive film pattern 4 is removed.

Next, as shown in FIGS. 4A and 4B, a second mask pattern 5, consisting of linear photoresist and extending in a second direction orthogonal to the first direction in which the first mask pattern 3 extends, is formed.

In this way, by using a linear mask pattern as the second mask pattern 5, excellent resolution and focus depth can be achieved and the adhesive area of the second mask pattern 5 to the conductive film pattern 4 can be secured sufficiently, as same as the case of the linear first mask pattern 3. Thus, it is advantageous to use a linear mask pattern for realizing miniaturization of electrodes.

Next, as shown in FIGS. 5A and 5B, by etching the conductive film pattern 4 using the second mask pattern 5, electrodes 6 are formed at positions where the first direction crosses the second direction. Then, the second mask pattern 5 remaining on the electrodes 6 is removed.

As described above, according to the electrode forming method of the first embodiment of the present invention, the conductive film pattern 4 is first formed by using the linear first mask pattern 3 extending in the first direction, and then the electrodes 6 are formed at positions where the first direction crosses the second direction by using the linear second mask pattern 5 extending in the second direction. This enables to secure the adhesive area of the first mask pattern 3 to the conductive film 2 and the adhesive area of the second mask pattern 5 to the conductive film pattern 6, sufficiently. Thus, since it is possible to prevent the resist from being peeled or destructed at the time of lithography and etching when forming the miniaturized electrodes 6, a defective pattern is not caused in the first and second mask patterns 3 and 5, whereby a fine capacitor element can be formed. Further, the linear first and second mask patterns 3 and 5 are excellent in the resolution and the focus depth compared with a case of using a dotted mask pattern, enabling to promote microprocessing of the electrodes 6.

It should be noted that although both the first and second mask patterns 3 and 5 use linear mask patterns including a plurality of electrodes 6 in the first embodiment of the present invention, they are not necessarily the linear shape. The mask patterns may take other shape than lines, provided that they have such areas of securing the adherence between the mask patterns and the base film.

Further, although the first mask pattern 3 and the second mask pattern 5 are arranged to be orthogonal in the first embodiment of the present invention, the electrodes can be formed at crossing positions if the first direction in which the first mask pattern 3 extends crosses the second direction in which the second mask pattern 5 extends. Therefore, the first direction in which the first mask pattern 3 extends does not necessarily cross perpendicular to the second direction in which the second mask pattern 5 extends. The first mask pattern 3 and the second mask pattern 5 may be arranged in any way, except that the first direction and the second direction come to be in parallel.

Further, although the explanation has been given for a case where the material of the conductive film 2 is platinum in the first embodiment of the present invention, materials such as platinum, iridium and ruthenium easily cause halation or the like, so these are difficult materials for miniaturizing electrodes made thereof. However, the electrode forming method according to the first embodiment of the present invention prevents the resist from being peeled or destructed at the time of lithography or etching so as not to cause a defective pattern in the mask pattern, whereby a metal film made of platinum iridium, ruthenium or the like can be used positively as an electrode.

### Second Embodiment

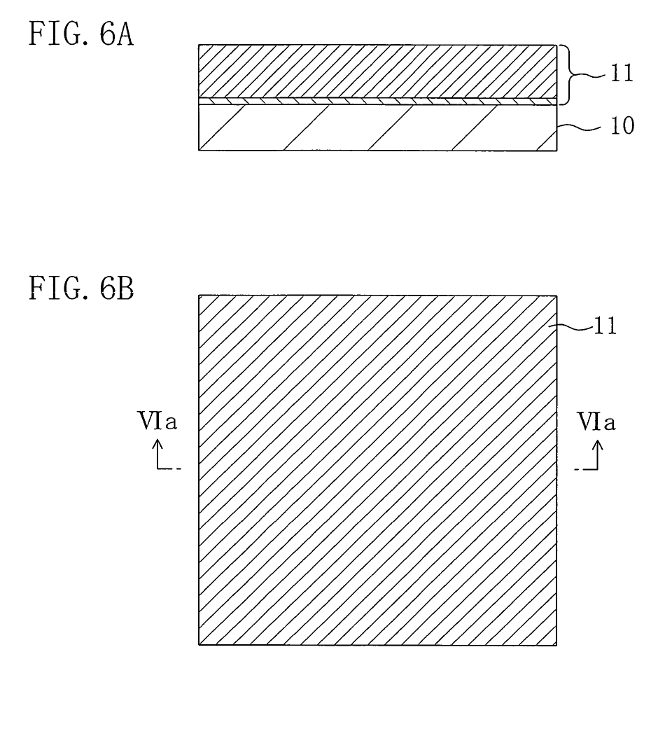

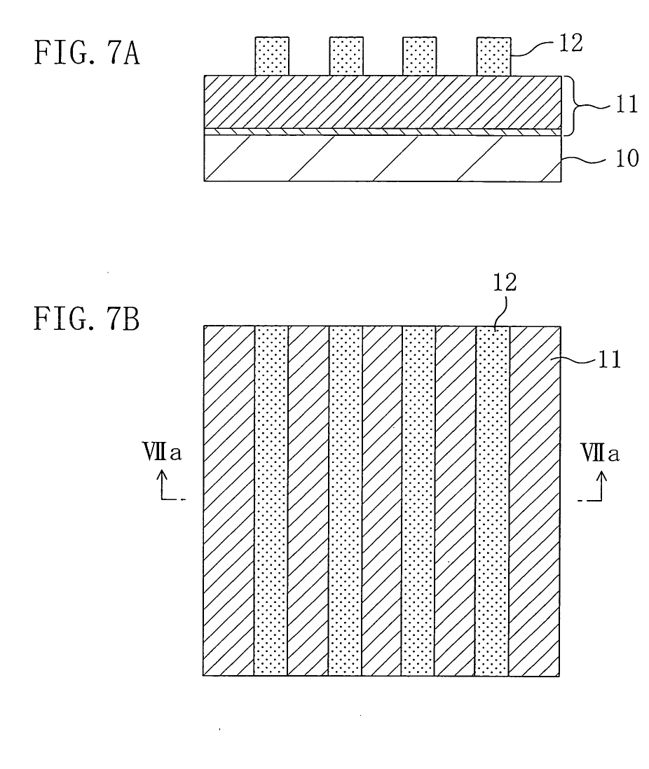

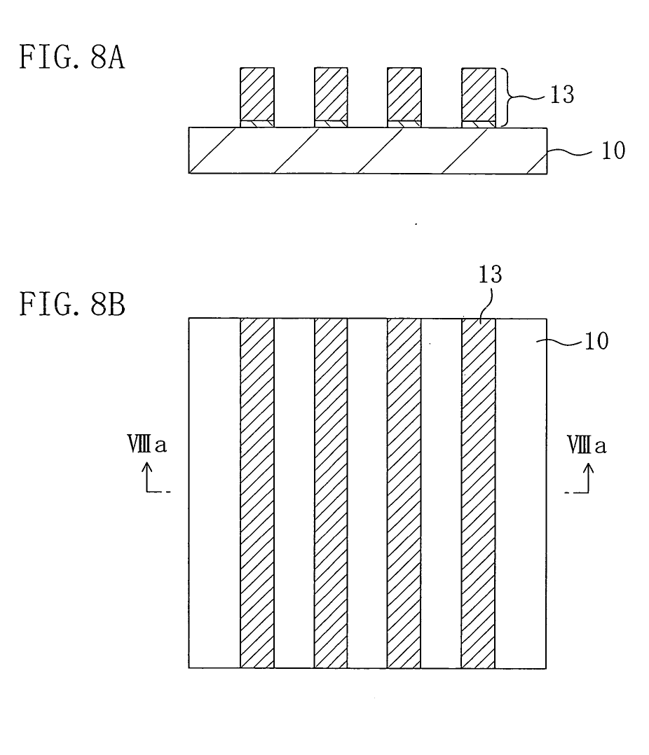

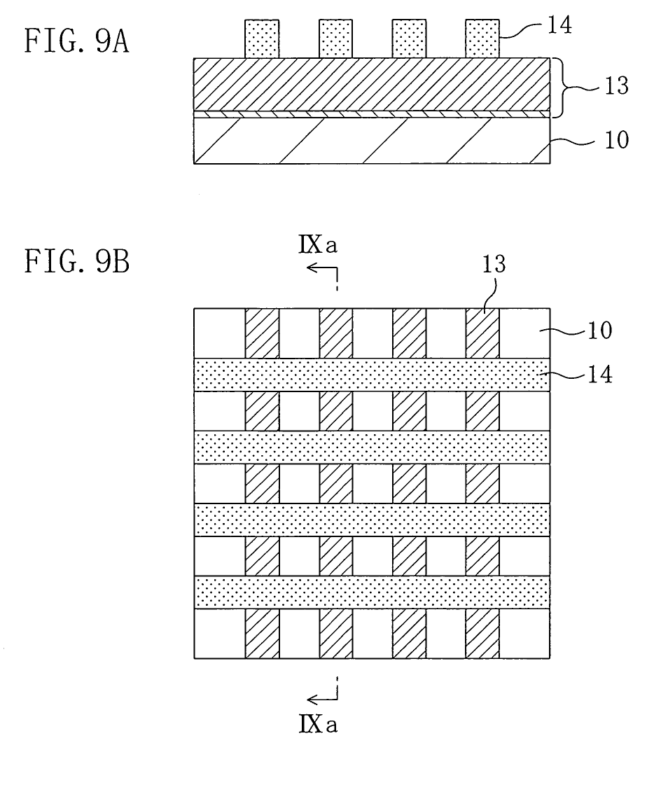

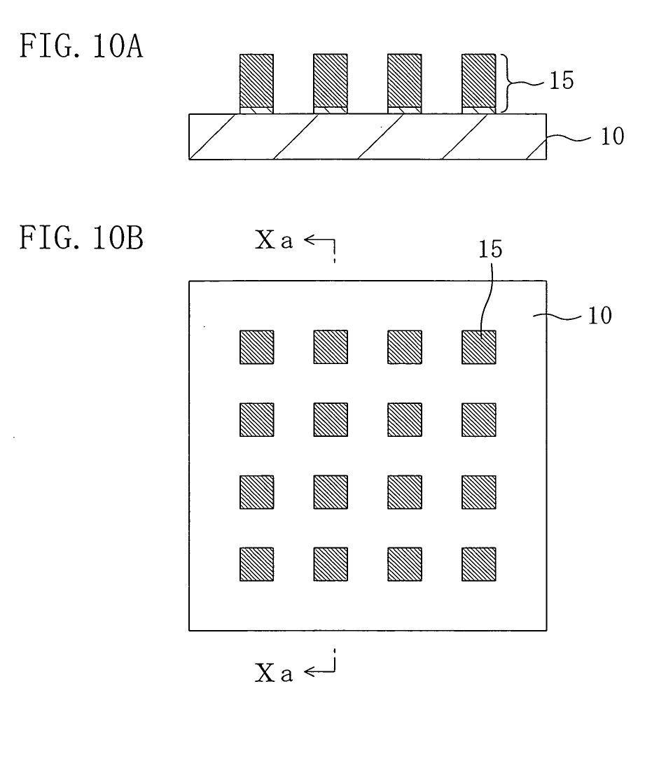

An electrode forming method according to a second embodiment of the present invention will be described below with reference to FIGS. 6A, 6B, 7A, 7B, 8A, 8B, 9A, 9B, 10A and 10B. FIGS. 6A, 7A, 8A, 9A and 10A are sequential process sectional views showing an electrode forming method, and FIGS. 6B, 7B, 8B, 9B and 10B are sequential process plan views showing the electrode forming method. Further, FIGS. 6A, 7A, 8A, 9A and 10A are sectional views taken along the line VIa-VIa of FIG. 6B, the line VIIa-VIIa of FIG. 7B, the line VIIIa-VIIIa of FIG. 8B, the line IXa-IXa of FIG. 9B, and the line Xa-Xa of FIG. 10B, respectively.

First, as shown in FIGS. 6A and 6B, a laminated conductive film 11, formed by laminating a titanium nitride film with a thickness of 20 mm and a platinum film with a thickness of 500 nm in sequence from the bottom, is deposited on a semiconductor substrate 10.

Next, as shown in FIGS. 7A and 7B, a first mask pattern 12 with a line width of 0.25 μm, consisting of photoresist and extending in a first direction, is formed on the laminated conductive film 11 by using a desired mask.

Next, as shown in FIGS. 8A and 8B, by etching the laminated conductive film 11 using the first mask pattern 12 as a mask, a laminated conductive film pattern 13 extending in the first direction is formed. Then, the first mask pattern 12 existing on the laminated conductive film pattern 13 is removed.

Next, as shown in FIGS. 9A and 9B, a second mask pattern 14 with a line width of 0.25 μm, consisting of photoresist and extending in a second direction orthogonal to the first direction in which the first mask pattern 12 extends, is formed on the laminated conductive film pattern 13.

Next, as shown in FIGS. 10A and 10B, by etching the laminated conductive film pattern 13 using the second mask pattern 14 as a mask, electrodes 15 are formed at positions where the first direction crosses the second direction. Then, the second mask pattern 14 existing on the electrodes 15 is removed.

The electrode 15 formed in this manner realizes a fine shape with a bottom area of 0.25×0.25 μm² and a height of 520 mm. Further, the electrode 15 realizes the aspect ratio of 2 or more.

The electrode 15 having such a fine shape can be used as a pillar-shaped lower electrode in a capacitor element of a solid stack type. In this case, in the general sequence of processes, a dielectric capacitor of a solid-stack structure can be formed by first forming the electrode 15 serving as a capacitor lower electrode, and then forming a dielectric film on the electrode 15 by the CVD, and then forming a capacitor upper electrode on the dielectric film by sputtering or the CVD.

As described above, according to the electrode forming method of the second embodiment of the present invention, the laminated conductive film pattern 13 is first formed by using the linear first mask pattern 12 extending in the first direction, and then the electrodes 15 are formed at positions where the first direction crosses the second direction by using the linear second mask pattern 14 extending in the second direction. This enables to secure the adhesive area of the first mask pattern 12 to the laminated conductive film 11 and the adhesive area of the second mask pattern 14 to the laminated conductive film pattern 13, sufficiently. Thus, since it is possible to prevent the resist from being peeled or destructed at the time of lithography and etching when forming the miniaturized electrodes 15, a defective pattern is not caused in the first and second mask patterns 12 and 14, whereby a fine capacitor element can be formed. Further, the linear first and second mask patterns 12 and 14 are excellent in the resolution and the focus depth compared with a case of using a dotted mask pattern, enabling to promote microprocessing of the electrodes 15.

Further, according to the electrode forming method of the second embodiment of the present invention, by using the first mask pattern 12 and the second mask pattern 14 in sequence, the laminated conductive film pattern 13 is first formed from the laminated conductive film 11 formed by laminating a titanium nitride film with a film thickness of 20 nm and a platinum film with a film thickness of 500 nm in sequence from the bottom, and then the electrodes 15 with the aspect ratio of 2 or more can be formed from the laminated conductive film pattern 13. In this way, according to the electrode forming method of the second embodiment of the present invention, the fine electrodes 15 with the aspect ratio of 1 or more can be formed easily.

It should be noted that although both the first and second mask patterns 12 and 14 use linear mask patterns including a plurality of electrodes 15 in the second embodiment of the present invention, they are not necessarily the linear shape. The mask patterns may take other shape than lines, provided that they have such areas of securing the adherence between the mask patterns and the base film.

Further, although the first mask pattern 12 and the second mask pattern 14 are arranged to be orthogonal in the second embodiment of the present invention, the electrodes 15 can be formed at crossing positions if the first direction in which the first mask pattern 12 extends crosses the second direction in which the second mask pattern 14 extends. Therefore, the first direction in which the first mask pattern 12 extends does not necessarily cross perpendicular to the second direction in which the second mask pattern 14 extends. The first mask pattern 12 and the second mask pattern 14 may be arranged in any way, except that the first direction and the second direction come to be in parallel.

Further, although the explanation has been given for a case where the material of the laminated conductive film 11 is platinum in the second embodiment of the present invention, materials such as platinum, iridium and ruthenium easily cause halation or the like, so these are difficult materials for miniaturizing electrodes made thereof. However, the electrode forming method according to the second embodiment of the present invention prevents the resist from being peeled or destructed at the time of lithography or etching so as not to cause a defective pattern in the mask patterns, whereby a metal film made of platinum iridium, ruthenium or the like can be used positively as an electrode.

### Third Embodiment

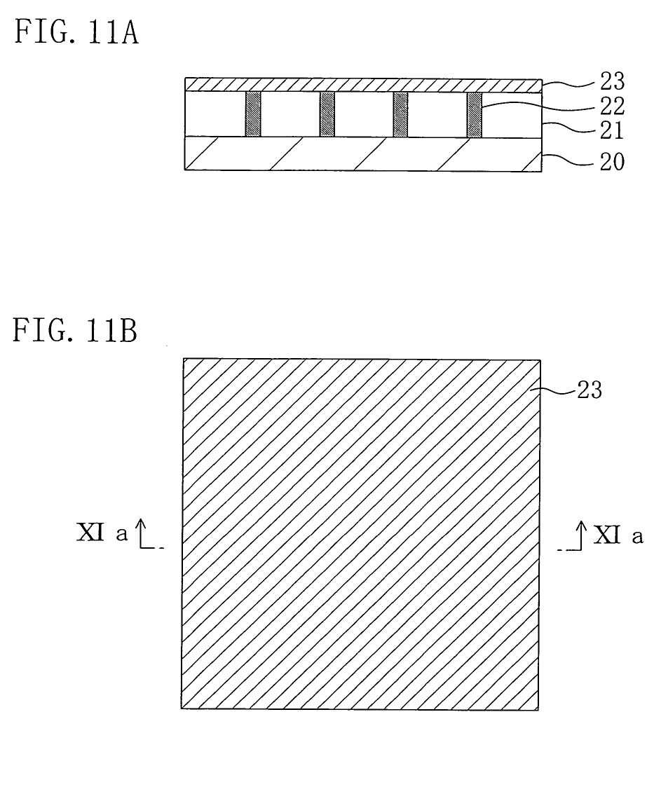

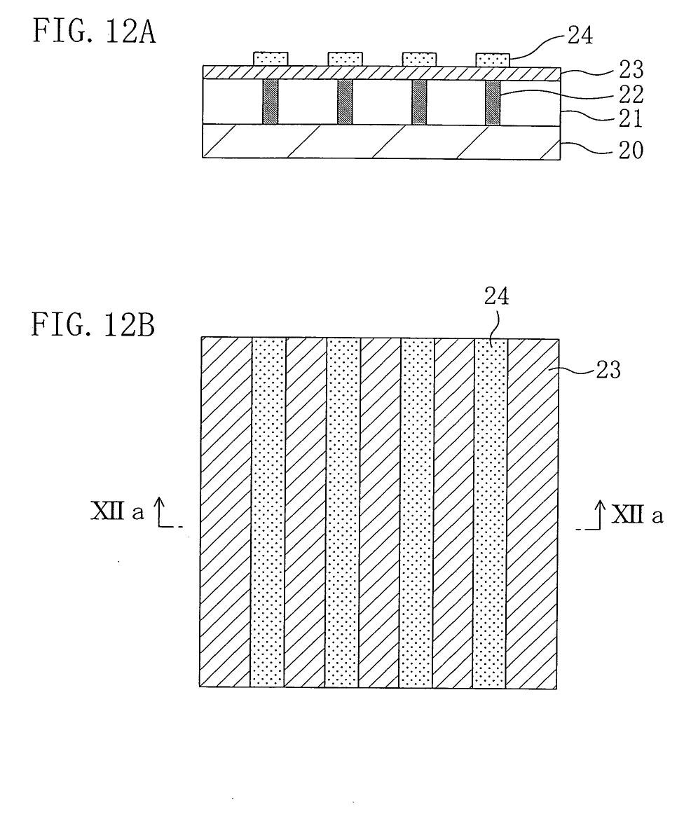

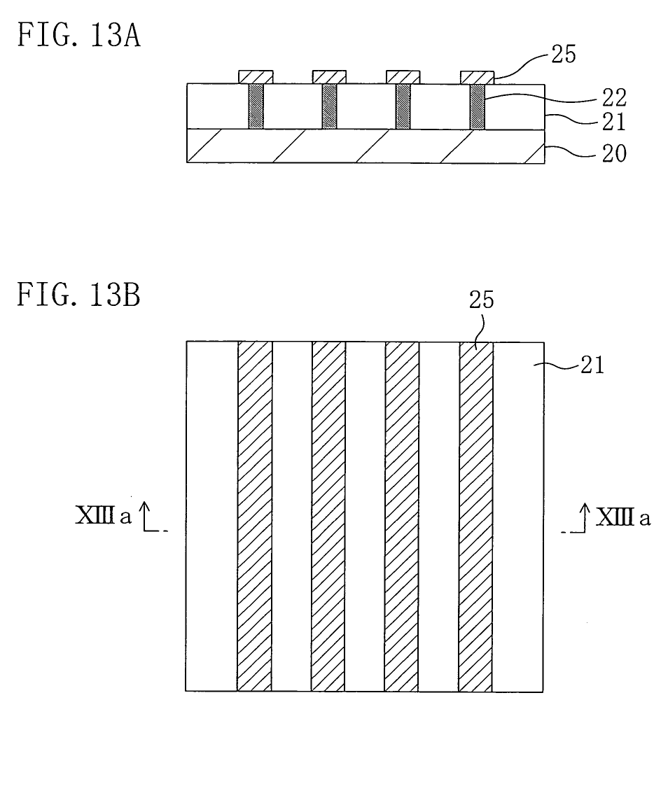

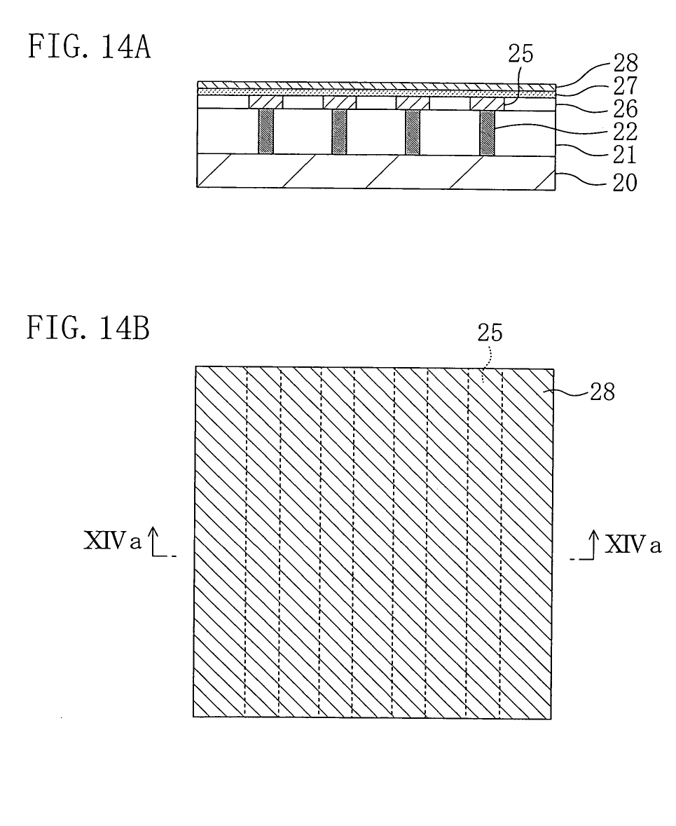

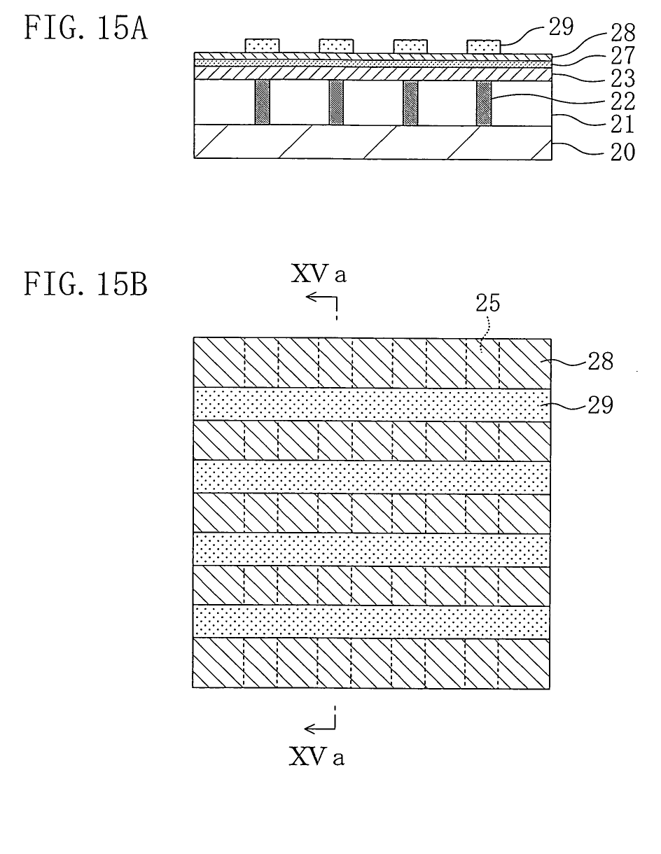

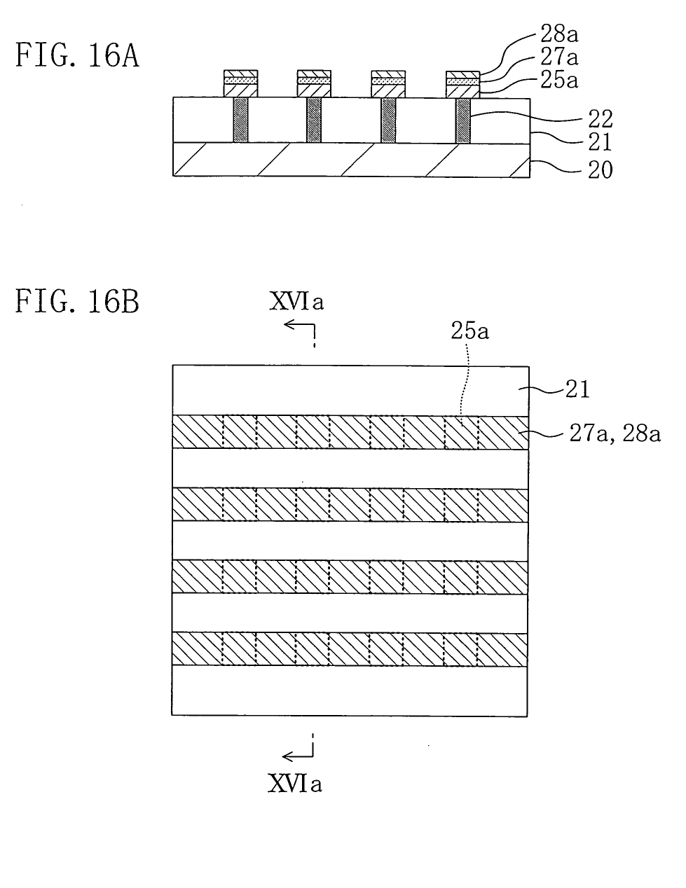

A capacitor element fabricating method according to a third embodiment of the present invention will be described below with reference to FIGS. 11A, 11B, 12A, 12B, 13A, 13B, 14A, 14B, 15A, 15B, 16A and 16B. FIGS. 11A, 12A, 13A, 14A, 15A and 16A are sequential process sectional views showing a capacitor element fabricating method, and FIGS. 11B, 12B, 13B, 14B, 15B and 16B are sequential process plan views showing the capacitor element fabricating method. Further, FIGS. 11A, 12A, 13A, 14A, 15A and 16A are sectional views taken along the line XIa-XIa of FIG. 11B, the line XIIa-XIIa of FIG. 12B, the line XIIIa-XIIIa of FIG. 13B, the line XIVa-XIVa of FIG. 14B, the line XVa-XVa of FIG. 15B and the line XVIa-XVIa of FIG. 16B, respectively.

First, as shown in FIGS. 11A and 11B, a first insulating film 21 consisting of a silicon oxide film with a thickness of 300 to 800 nm is formed on a semiconductor substrate 20. Next, on the first insulating film 21, contact plugs 22 formed by filling a tungsten film or a polysilicon film, extending through the first insulating film 21 and connecting with active regions (not shown) of the semiconductor substrate 20, are formed. Then, on the first insulating film 21 and on the contact plugs 22, a first conductive film 23 is deposited. The first conductive film 23 serves to prevent oxidization when a dielectric film described later is crystallized, and has a laminated structure consisting of an oxidization preventive film including iridium or iridium oxide with a thickness of 50 to 300 nm and a platinum film with a thickness of 50 to 200 nm forming lower electrodes of a capacitor element.

Next, as shown in FIGS. 12A and 12B, on the first conductive film 23, a first mask pattern 24 consisting of photoresist and extending in a first direction is formed by using a desired mask.

Next, as shown in FIGS. 13A and 13B, by etching the first conductive film 23 using the first mask pattern 24, a first conductive film pattern 25 is formed. Then, the first mask pattern 24 existing on the first conductive film pattern 25 is removed.

Next, as shown in FIGS. 14A and 14B, a second insulating film 26 consisting of a silicon oxide film is formed on the first insulating film 21 so as to fill the periphery of the first conductive film pattern 25 by the CMP or etching back. Then, on the first conductive film pattern 25 and on the second insulating film 26, a dielectric film 27 and a second conductive film 28 are formed in sequence from the bottom.

Next, as shown in FIGS. 15A and 15B, a second mask pattern 29, consisting of photoresist and extending in a second direction orthogonal to the first direction in which the first mask pattern 24 extends, is formed on the second insulating film 26 by using a desired mask.

Next, as shown in FIGS. 16A and 16B, by etching the second conductive film 28, the dielectric film 27 and the first conductive film pattern 25 by using the second mask pattern 29, a capacitor element composed of a capacitor upper electrode 28a, consisting of the second conductive film 28, a capacitor insulating film 27a, consisting of the dielectric film 27, and capacitor lower electrodes 25a, consisting of the first conductive film pattern 25, is formed. Then, the second mask pattern 29 remaining on the capacitor upper electrode 28a is removed.

As described above, according to the capacitor element fabricating method of the third embodiment of the present invention, the first conductive film pattern 25 is first formed by using the linear first mask pattern 24 extending in the first direction, and then the capacitor element with the lower electrodes 25 at positions where the first direction crosses the second direction is formed by using the linear second mask pattern 29 extending in the second direction. This enables to secure the adhesive area of the first mask pattern 24 to the first conductive film 23 and the adhesive area of the second mask pattern 29 to the second conductive film 28, sufficiently. Thus, since it is possible to prevent the resist from being peeled or destructed at the time of lithography and etching when forming the miniaturized capacitor element, a defective pattern is not caused in the first and second mask patterns 24 and 29, whereby a fine capacitor element can be formed. Further, the linear first and second mask patters 24 and 29 are excellent in the resolution and the focus depth compared with a case of using a dotted mask pattern, enabling to promote microprocessing of the capacitor element.

Further, according to the capacitor element fabricating method of the third embodiment of the present invention, the second conductive film 28, the dielectric film 27 and the first conductive film pattern 25 are etched by using the second mask pattern 29, whereby the capacitor element can be formed in a self-aligned manner.

It should be noted that although both the first and second mask patterns 24 and 29 use linear mask patterns including a plurality of capacitor lower electrodes 25a in the third embodiment of the present invention, they may take other shape than lines, provided that they have such areas of securing the adherence between the mask patterns and the base film.

Further, although the first mask pattern 24 and the second mask pattern 29 are arranged to be orthogonal in the third embodiment of the present invention, the capacitor lower electrodes 25a can be formed at crossing positions if the first direction in which the first mask pattern 24 extends crosses the second direction in which the second mask pattern 29 extends. Therefore, the first direction in which the first mask pattern 24 extends does not necessarily cross perpendicular to the second direction in which the second mask pattern 29 extends. The first mask pattern 24 and the second mask pattern 29 may be arranged in any way, except that the first direction and the second direction come to be in parallel.

### Fourth Embodiment

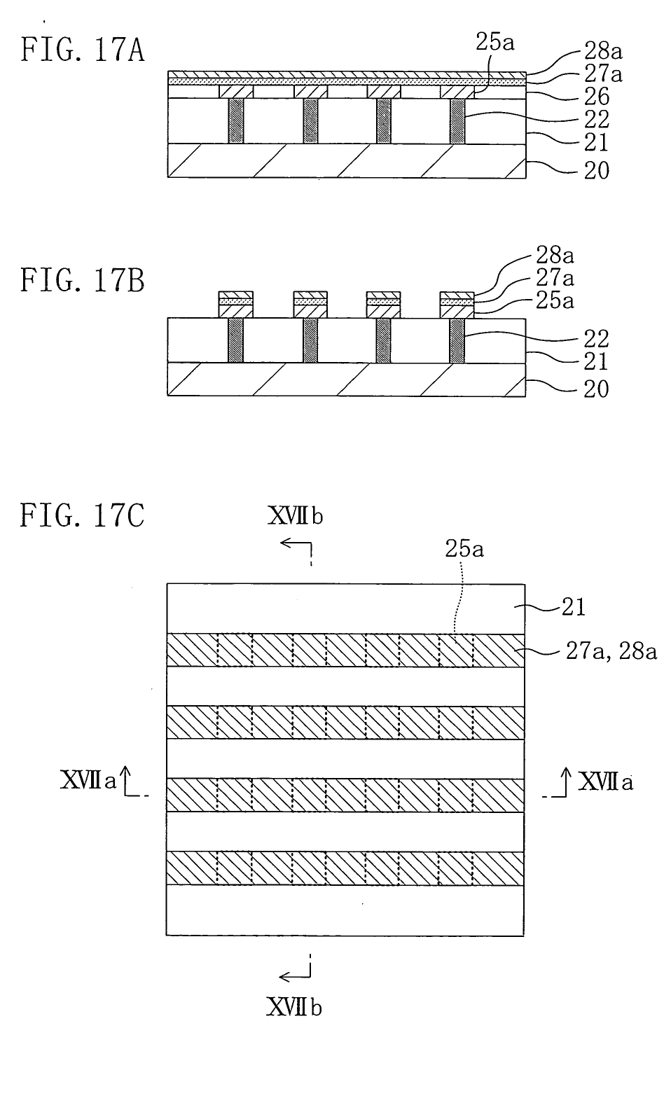

A capacitor element according to a fourth embodiment of the present invention will be described below with reference to FIGS. 17A to 17C.

FIGS. 17A and 17B are sectional views showing the structure of the capacitor element according to the fourth embodiment of the present invention, and FIG. 17C is a plan view showing the structure of the capacitor element according to the fourth embodiment of the present invention. Note that FIG. 17A is a sectional view taken along the line XVIIa-XVIIa of FIG. 17C, and FIG. 17B is a sectional view taken along the line XVIIb-XVIIb of FIG. 17C. Further, since the capacitor element according to the fourth embodiment can be formed by using the capacitor element fabricating method according to the aforementioned third embodiment, the same numerals are used for the parts corresponding to those in the structure of the capacitor element of the third embodiment.

As shown in FIGS. 17A to 17C, the first insulating film 21 consisting of a silicon oxide film with a thickness of 300 to 800 nm is formed on the semiconductor substrate 20. In the first insulating film 21, the contact plugs 22, consisting of a tungsten film or a polysilicon film linked with active regions (not shown) of the semiconductor substrate 20 and extending through the first insulating film 21 are formed. On the first insulating film 21, the capacitor lower electrodes 25a connecting with the upper end of the contact plugs 22 are formed. The capacitor lower electrode 25a serves to prevent oxidization when the dielectric film 27a described later is crystallized, and has a laminated structure in which an oxide barrier film including iridium or iridium oxide with a thickness of 50 to 300 nm and a platinum film with a thickness of 50 to 200 nm are laminated in sequence from the bottom.

On the first insulating film 21 and the contact plugs 22, the capacitor insulating film 27a, consisting of an SBT film with a thickness of 5 to 100 nm as a dielectric film, and the capacitor upper electrode 28a, consisting of a platinum film with a thickness of 5 to 100 nm, are formed so as to fill the periphery of the capacitor lower electrodes 25a.

As described above, the capacitor element according to the fourth embodiment of the present invention includes: a plurality of capacitor lower electrodes 25a aligned in the arrow XVIIb direction in FIG. 17C and the side faces of which are positioned on a face extending in the arrow XVIIb direction; the capacitor insulating film 27a formed on the plurality of capacitor lower electrodes 25a so as to extend in the arrow XVIIb direction; and the capacitor upper electrode 28a formed on the capacitor insulating film 27a so as to extend in the arrow XVIIb direction. In other words, the side faces of the plurality of capacitor lower electrodes 25a positioned on the face, the side faces of the capacitor insulating film 27a extending in the arrow XVIIb direction, and the side faces of the capacitor upper electrode 28a in the arrow XVIIb direction are flush with one another. Further, the capacitor element, when viewed from the arrow XVIIb direction, does not require a mask alignment margin, whereby a capacitor element having the same structure as that realized in a case where etching is performed collectively by using one mask can be realized. As a result, the configuration of the side faces of the capacitor element can be formed in a self-aligned manner, enabling to miniaturize the capacitor element and to promote miniaturization of the cell in a capacitor element of a type in which the capacity of the lower electrode is defined.

In a conventional capacitor element of a type in which the capacity of the lower electrode is defined, a capacitor lower electrode must be covered with a dielectric film and a capacitor upper electrode, so that a mask alignment margin is required. Further, since the shifted amount of the dielectric film or the capacitor upper electrode to the capacitor lower electrode may be asymmetry laterally, depending on the mask alignment, which causes the electric flux line generated between the capacitor lower electrode and the capacitor upper electrode to be asymmetry. This may cause difference or dispersion of characteristics between capacitor elements.

However, according to the structure of the capacitor element of the fourth embodiment, the capacitor element can be formed in a self-aligned manner, enabling to miniaturize electrodes and to promote miniaturization of the cell in a capacitor element of a type in which the capacity of the lower electrode is defined.

Although the capacitor insulating film 27a and the capacitor upper electrode 28a are linearly formed containing a plurality of capacitor lower electrodes 25a in the fourth embodiment of the present invention, they may not be formed in the linear shape. Further, although the explanation has been given for the case where the plane shape of the capacitor lower electrode 25a is a square, it may not be a square, provided that the capacitor element is formed at a part where the capacitor lower element 25a, the capacitor insulating film 27a and the capacitor upper electrode 28a are stacked.

In the capacitor element and the method for fabricating the same according to the present invention, the electrodes forming the capacitor element are processed by using the first mask pattern extending in the first direction and the second mask pattern extending in the second direction different from the first direction, whereby the resist is prevented from being peeled or destructed at the time of lithography or etching when forming the miniaturized capacitor element, enabling to prevent a defective pattern or disappearance in the first and second mask patterns. Thus, the present invention is effective in fabricating a ferroelectric electrode element in which a dielectric material such as a ferroelectric film or a high dielectric film is used as a capacitor insulating film.

1. An electrode forming method comprising the steps of:
forming a conductive film on a substrate;
forming, on the conductive film, a first mask pattern extending in a first direction;
forming a conductive film pattern by etching the conductive film using the first mask pattern;
removing the first mask pattern;
forming, on the substrate and on the conductive film pattern, a second mask pattern extending in a second direction different from the first direction; and
forming an electrode by etching the conductive film pattern using the second mask pattern.

2. The electrode forming method of claim 1, wherein
the conductive film includes a metallic material.

3. The electrode forming method of claim 1, wherein
an aspect ratio of the electrode is 1 or more.

4. A capacitor element fabricating method comprising the steps of:
forming a first conductive film on a substrate;
forming, on the first conductive film, a first mask pattern extending in a first direction;
forming a conductive film pattern by etching the first conductive film using the first mask pattern;
removing the first mask pattern;
forming, on the substrate, a dielectric film and a second conductive film in sequence from a bottom so as to cover the conductive film pattern;
forming, on the second conductive film, a second mask pattern extending in a second direction different from the first direction;
by etching the second conductive film, the dielectric film and the conductive film pattern by using the second mask pattern, forming a capacitor element composed of a capacitor lower electrode formed of the conductive film pattern, a capacitor insulating film formed of the dielectric film, and a capacitor upper electrode formed of the second conductive film.

5. The capacitor element fabricating method of claim 4, wherein
at least one of the first conductive film and the second conductive film includes a metallic material.

6. A capacitor element comprising:
a plurality of capacitor lower electrodes aligned in a prescribed direction and side faces of which are positioned on a face extending in the prescribed direction;
a capacitor insulating film formed on the plurality of capacitor lower electrodes so as to extend in the prescribed direction; and
a capacitor upper electrode formed on the capacitor insulating film so as to extend in the prescribed direction, wherein
the side faces of the plurality of capacitor lower electrodes positioned on the face, a side face of the capacitor insulating film extending in the prescribed direction, and a side face of the capacitor upper electrode extending in the prescribed direction are flush with one another.

7. The capacitor element of claim 6, wherein
at least one of the capacitor lower electrode and the capacitor upper electrode includes platinum or iridium.

8. The capacitor element of claim 6, wherein
the capacitor insulating film is made of a ferroelectric material having a bismuth layered perovskite structure, lead zirconate titanate, barium strontium titanate, or tantalum pentoxide.
